(19) United States
(12) Patent Application Publication
(10) Pub. No.: US 2024/0347372 A1
(43) Pub. Date: Oct. 17, 2024

(54) SUSCEPTOR

(71) Applicant: Applied Materials, Inc., Santa Clara, CA (US)

(72) Inventors: Balakrishnam R. JAMPANA, San Jose, CA (US); Masato ISHII, Sunnyvale, CA (US); Zhepeng CONG, San Jose, CA (US)

(21) Appl. No.: 18/632,421

(22) Filed: Apr. 11, 2024

Related U.S. Application Data
(60) Provisional application No. 63/458,921, filed on Apr. 12, 2023.

(51) Int. Cl. H01L 21/687; C23C 16/458; C30B 25/12

(52) U.S. Cl. CPC H01L 21/68785; C23C 16/4583; H01L 21/6875; C30B 25/12

(57) ABSTRACT

Described herein are a susceptor, processing chambers having the same, and method for substrate processing using the same. In one example, a susceptor for supporting a substrate during processing is provided. The susceptor has a disk shaped body that includes a rim circumscribing an inner region. The inner region is recessed to form a recessed pocket that is configured to receive a substrate. A plurality of bumps extend radially into the inner region that are configured to contact an outer edge of the substrate when the substrate is disposed in the recessed pocket. A venting region is defined within the inner region. The venting region is defined by a plurality of vent holes formed through the body. The venting region terminates at a radius originating from a centerline of the body that is at least 4.0 millimeter less than a radius defining an inner wall of the rim.

### CROSS-REFERENCE TO RELATED APPLICATIONS

This application claims priority to U.S. Provisional Patent Application No. 63/458,921, filed Apr. 12, 2023, which is herein incorporated by reference.

### BACKGROUND

### Field

Embodiments described herein generally relate to susceptors for use in semiconductor processing equipment, and related methods and processing chambers using the same.

### Description of the Related Art

In the fabrication of integrated circuits, deposition processes are used to deposit films of various materials upon semiconductor substrates. Epitaxy is a deposition process that grows a thin, ultra-pure layer, usually of silicon or germanium, on a surface of a substrate. Forming an epitaxial layer on a substrate with uniform thickness across the surface of the substrate can involve precise temperature control.

The susceptor that supports the substrate during epitaxial deposition processes often have an impact on the quality and/or uniformity of the deposited film. Changes to process recipes and/or the material being deposited often results in a susceptor that once enabled films to be deposited in acceptable quality and/or uniformity becoming unacceptable.

Thus, there is a need for an improved susceptor, and methods and processing chambers having the same.

### SUMMARY

Described herein are susceptors, and methods and processing chambers having the same. In one example, a susceptor for supporting a substrate during processing is provided. The susceptor has a disk shaped body that includes a rim circumscribing an inner region. The inner region is recessed relative to the rim to form a recessed pocket that is configured to receive a substrate. A plurality of bumps extend radially into the inner region that are configured to contact an outer edge of the substrate when the substrate is disposed in the recessed pocket. A venting region is defined within the inner region. The venting region is defined by a plurality of vent holes formed through the body. The venting region terminates at a radius originating from a centerline of the body.

In some examples, the venting region is at least 4.0 millimeter less than a radius defining an inner wall of the rim.

In another example, a susceptor includes a disk shaped body that has a first side and a second side. A centerline of the body extends normally through the first and second sides. The body includes a rim circumscribing an inner region. The rim has an inner diameter wall defined at a first radius relative to the centerline The inner region is circumscribed by the inner diameter wall of the rim and is recessed on the first side relative to the rim to form a recessed pocket that is configured to receive a substrate. A plurality of bumps extend radially into the inner region from the inner diameter of the rim. The bumps are configured to contact an outer edge of the substrate when the substrate is disposed in the recessed pocket. A venting region is defined within the inner region. The venting region is defined by a plurality of vent holes formed through the body. The venting region terminates at a radius originating from a centerline of the body that is at least 4.0 millimeter less than a radius defining an inner wall of the rim. The plurality of vent holes are at least 2 mm from the plurality of bumps. A plurality of lift pin holes formed through the inner region. The lift pin holes have a diameter greater than a diameter of the vent holes. A top surface of the recessed region has pattern of substrate support posts separated by a plurality of venting channels. The plurality of vent holes exiting the top surface open into the plurality of venting channels.

In some examples, a non-venting region defined within the inner region and circumscribes the venting region. The non-venting region is devoid of holes.

In one example, a susceptor for supporting a substrate during processing is provided. The susceptor has a disk shaped body. The body has a border ring and a web disposed in the border ring. The web has a top surface coupled to an inside diameter wall of the border ring. The web has a bottom surface coupled to a bottom surface of the border ring. The web has a top surface recessed below a top surface of the border ring. The web further includes a plurality of holes formed therethrough and a plurality of substrate support posts extending from the top surface of the web a distance that terminates below the top surface of the border ring.

In some examples, the substrate support posts of the susceptor form a planar substrate support surface. The distal ends of the substrate support posts may be configured to reduce the contact area with the substrate. For example, distal ends of the substrate support posts may be curved, have an edge radius or chamfer, be full round, be domed shaped or have another suitable geometry.

In some examples, a substrate supported on the susceptor is solely supported by the substrate support posts.

In some examples, the susceptor support posts have a length sufficient to form a plenum between the substrate disposed on the susceptor support posts and a top surface of the web.

In some examples, the susceptor support posts are arranged in an X/Y grid. In other examples, the susceptor support posts are radially aligned and/or form concentric rings. The density of susceptor support posts may vary across the web such as to create regions having more support posts compared to other regions, such as the center of the web compared to the edge of the web. Some susceptor support posts may be different sectional areas.

In some examples, the plurality of holes formed therethrough the web are arranged in an X/Y grid. In other examples, the holes are radially aligned and/or form concentric rings. The density and/or open area of holes may vary across the web such as to create regions having more holes and/or open are compared to other regions, such as the center of the web compared to the edge of the web. Some holes may be different sectional areas. Additionally, although the holes are should with a circular cross section, the sectional profile of the holes may be other than circular.

In another example, the susceptor includes a plurality of substrate centering bumps coupled to the inside diameter wall of the border ring.

In another example, a processing chamber is provided that includes a chamber having a susceptor disposed in a processing volume. The susceptor is configured as described herein.

In yet another example, a method for processing a substrate is provided that includes heating a substrate supported on a susceptor in a processing chamber, and forming a film on the substrate while in the processing chamber. The susceptor may be configured as described herein.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial schematic side cross-sectional view of a processing chamber having a susceptor disposed therein.

FIG. 2A is an isometric view of one example of a susceptor that may be utilized in the processing chamber of FIG. 1.

FIG. 2B is partial cross sectional side view of the susceptor illustrated in FIG. 2A.

FIG. 2C is partial top view of the susceptor illustrated in FIG. 2A.

FIG. 3A is partial cross sectional side view of the susceptor illustrated in FIG. 2A.

FIG. 3B is partial top view of the susceptor illustrated in FIG. 3A.

FIG. 3C is partial cross sectional side view of the susceptor illustrated in FIG. 3A.

FIG. 4 is a partial cross sectional side view of another example of susceptor that may be utilized in the processing chamber of FIG. 1.

FIG. 5A is a partial cross sectional side view of another example of susceptor that may be utilized in the processing chamber of FIG. 1.

FIG. 5B is partial top view of the susceptor illustrated in FIG. 5A.

FIGS. 6A-6C are sectional views of various examples of substrate support post of a susceptor that may be utilized in the processing chamber of FIG. 1.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a non-specific plane of reference. This non-specific plane of reference may be vertical, horizontal or other angular orientation.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a susceptor, processing chambers having the same, and related methods, for semiconductor manufacturing. It is contemplated that the processing chambers and susceptor may be utilized for processing substrates other than semiconductor wafers, such as LED wafers, plastic substrates, windows, solar panels, and flat panel displays, among others. The susceptor includes a plurality of venting holes that reduces sliding between the susceptor and the substrate being processed thereon. The reduced extends the service life of the susceptor, while reducing particle generation and substrate edge damage. Such benefits advantageously reduces the cost of substrate processing. The venting holes are disposed in a central region of the substrate receiving pocket. The pattern of venting holes terminates well away from an inner diameter wall of the substrate receiving pocket and edge of the substrate, which effectively reduces unwanted leakage of deposition gases though the susceptor so that the region of the processing chamber below the susceptor remains cleaner longer, thus advantageously extending the chamber cleaning service interval which also advantageously increase processing throughput and production yields.

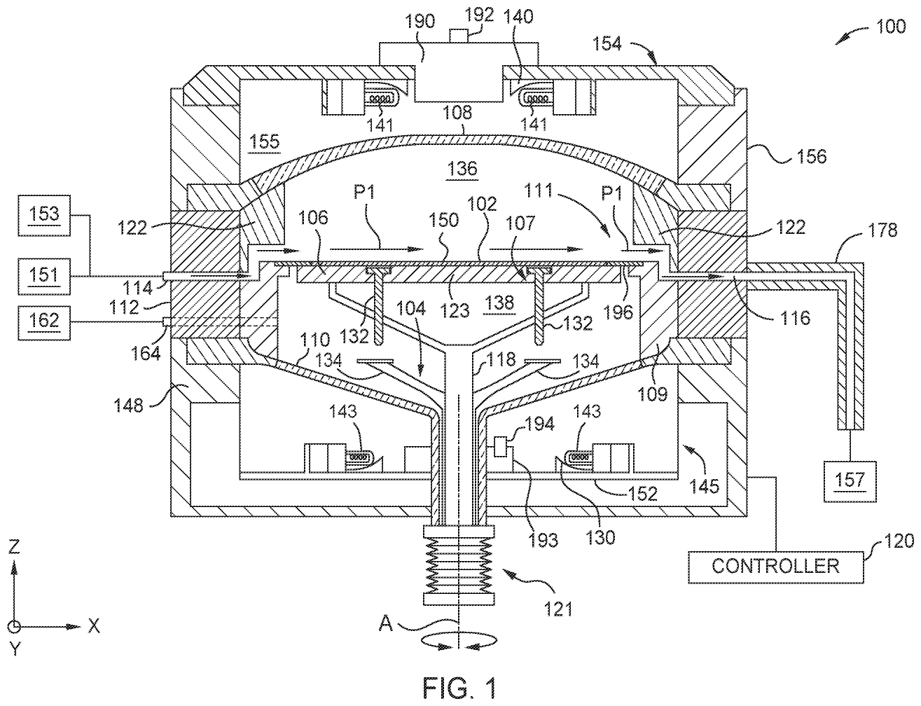

FIG. 1 is a partial schematic side cross-sectional view of a processing chamber 100 including a susceptor 123, according to one or more embodiments. The processing chamber 100 may be a deposition chamber or other type of vacuum processing chamber. In one or more embodiments, the processing chamber 100 is an epitaxial deposition chamber. The processing chamber 100 may be utilized to grow an epitaxial film on a substrate 102. The processing chamber 100 creates a cross-flow of precursors across a top surface 150 of the substrate 102. In one or more embodiments, the processing chamber 100 is used for rapid thermal processing. The processing chamber 100 can operate under vacuum, such as, at reduced pressures or near atmospheric pressure.

The processing chamber 100 includes an upper body 156, a lower body 148 disposed below the upper body 156, and a flow module 112 disposed between the upper body 156 and the lower body 148. The upper body 156, the flow module 112, and the lower body 148 form at least part of a chamber body that encloses a processing volume 136. The upper body 156, the flow module 112, and the lower body 148 are centered about a centerline A. Disposed within the processing volume of the chamber body is a substrate support 106, an upper window 108 (such as an upper dome), a lower window 110 (such as a lower dome), a plurality of upper heat sources 141, and a plurality of lower heat sources 143. The centerline A is also the centerline of the substrate support 106, the upper window 108, and the lower window 110. As shown, a controller 120 is in communication with the processing chamber 100 and is used to control processes and methods, such as the operations of the methods described herein.

In one or more embodiments, the heat sources (such as the heat sources 141, 43) discussed herein include radiant heat sources such as lamps, for example halogen lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein.

The substrate support 106 is disposed between the upper window 108 and the lower window 110. The substrate support 106 includes a susceptor 123 that supports the substrate 102.

The plurality of upper heat sources 141 are disposed between the upper window 108 and a lid 154. The plurality of upper heat sources 141 form a portion of the upper heat source module 155. Upper heat sources 141 provide heat to the substrate 102 and/or the susceptor 123 of the substrate support 106. Upper heat sources 141 can be, for example, tungsten filament heat sources or higher power LEDs. The plurality of upper heat sources 141 can direct radiation, such as infrared radiation, through the upper window 108 to heat the substrate 102 and/or susceptor 123 of the substrate support 106. The lid 154 may include a plurality of sensors disposed therein for measuring the temperature within the processing chamber 100.

The plurality of lower heat sources 143 are disposed between the lower window 110 and a floor 152. The plurality of lower heat sources 143 form a portion of a lower heat source module 145. Lower heat sources 143 can be, for example, tungsten filament heat sources or higher power LEDs. The plurality of lower heat sources 143 can direct radiation, such as infrared radiation, through the lower window 110 to heat the substrate 102 and/or the substrate support 106.

The upper heat sources 141 above the susceptor 123 can be installed adjacent to an upper shell assembly 190 and within or adjacent to an upper reflector 140. The upper reflector 140 can surround the perimeter of the upper shell assembly 190. Generally, the upper reflector 140 and/or the upper shell assembly 190 can be formed of a reflective metallic alloy, such as a reflective aluminum alloy. An upper temperature sensor 192, such as a pyrometer, can be installed in or adjacent to the upper shell assembly 190 to detect a temperature of the substrate 102 during processing.

Lower heat sources 143 can be installed within or adjacent to a lower reflector 130 and within or adjacent to a lower shell assembly 193. The lower reflector 130 can surround the lower shell assembly 193. Generally, the lower reflector 130 and/or the lower shell assembly 193 can be formed at least partially (such as partially or entirely) of a reflective metallic alloy, for example a reflective aluminum alloy. A lower temperature sensor 194, such as a pyrometer, can be installed in the lower shell assembly 193 to detect a temperature of the susceptor 123 or the backside of the substrate 102. One or both of the lower reflector 130 and/or the lower shell assembly 193 may be fabricated as later described below with reference to an upper shell assembly 190 and/or an upper reflector 140.

Although FIG. 1 shows the same size and number of heat sources 141, 143 installed above and below the upper and lower windows, 108, and 110 respectively, different types, intensity, wavelength, numbers, and/or sizes of heat sources may be installed within or adjacent to one or more of the reflectors 130, 140. Additionally, upper heat sources 141 and lower heat sources 143 may be disposed in additional and/or alternative locations.

The upper reflector 140, the lower reflector 130, the upper shell assembly 190, and the lower shell assembly 193 (and/or other component(s) including the metallic alloy) can be manufactured by processes such as, but not limited to, melt spinning, or any other process including rapid liquid quenching, gaseous quenching, and/or rate-controlled chemical and solid reactions. One or more surfaces of the metallic alloy can further be smoothened for increased surface reflectivity. In one or more embodiments, the metallic alloy is an aluminum alloy. In one or more embodiments, the metallic alloy is a brass alloy that includes copper and zinc. In one or more embodiments, the metallic alloy includes a post-transition metal (such as aluminum) and one or more transition metals (such as one or more of iron, nickel, copper, manganese, molybdenum, and/or zirconium). The metallic alloy has an alloy composition that includes a post-transition atomic percentage (such as an aluminum atomic percentage) that is at least 80% and a transition atomic percentage of the one or more transition metals that is at least 5%. In one or more embodiments, a sum of the post transition atomic percentage and the transition atomic percentage is at least 95%.

In one or more embodiments, the metallic alloy includes aluminum (e.g., having an aluminum atomic percentage of at least 80%) and at least one of silicon, copper, and/or magnesium (e.g., having a combined atomic percentage of at least 5%). In one or more embodiments, a sum of the aluminum atomic percentage and the combined atomic percentage is at least 95%.

The smoothening of the one or more outer surfaces includes polishing the one or more outer surfaces. In one or more embodiments, the polishing includes magnetorheological finishing (MRF). In one or more embodiments, the polishing includes plasma electrolytic polishing. Other polishing techniques are contemplated.

Using the metallic alloy, an additional reflective coating may not be needed since the metallic alloy itself already has, or can be polished to have, a high reflectivity. In addition, the metallic alloy has high shape stability, low thermal expansion, high thermal conductivity, and is lightweight.

Reflectivity of light on the surface of a material depends on the surface finish and also on the microstructure of crystals on the surface. Such as by using melting, the metallic alloy is formed with a unique structure. That is, instead of the solid metallic alloy being composed of discrete organized large crystals as in some microstructures, the metallic alloy is formed of a microstructure with no specific organization or organized grain boundaries. To facilitate obtaining desired properties for a targeted application, an amorphous microstructure can be further tailored by thermal processing to a partially amorphous structure containing ultra-fine crystals or to a completely crystallized structure with ultra-fine crystals. In this way, ultra-fine crystals can be formed in the microstructure. In one or more embodiments, the metallic alloy has ultra-fine crystalline grains on the surface, and has high surface reflectivity. Further, polishing and surface finishing of the metallic alloy causes the surface roughness to be equal to or less than 5 nanometer, such as equal to or less than 1 nanometer. This reduced surface roughness increases the reflectivity of the metallic alloy.

A reflectivity of one or more reflective surfaces of the chamber component(s) that include the metallic alloy is at least 90% for energy (e.g., light) having a wavelength in the infrared range. In one or more embodiments, the reflectivity is within a range of 90% to 99%. In one or more embodiments, the reflectivity is at least 95%, such as at least 98%.

When the disclosed metallic alloy is used as a chamber component (such as upper reflector 140 or lower reflector 130) in a processing chamber 100, it can get very hot due to its proximity to upper heat sources 141 and/or lower heat sources 143. At these high temperatures, the reflective surface(s) of the reflectors can get very hot and therefore oxidized to the pressure of the surrounding air. This oxidation in turn can reduce the reflectivity of the reflective surface(s) of the metallic alloy. To reduce or eliminate the oxidation and/or reflectivity reduction, the metallic alloy can be coated with an IR transparent protective coating.

In one or more embodiments, the IR transparent protective coating is a single thin layer of material, includes multiple thin layers of materials, or includes a laminated layer structure. The IR transparent coating may include one or more of a metal oxide layer, a metal fluoride layer, and/or a metal oxyfluoride layer. In one or more embodiments, the IR transparent coating is a stack of layers, with each layer in the stack having one or more of an oxide, fluoride, and/or oxyfluoride composition. In one or more embodiments, the IR transparent coating is made of at least one of: aluminum oxide, other oxide(s), magnesium fluoride, other fluoride(s), magnesium oxyfluoride, and/or other oxyfluoride(s). The present disclosure contemplates that other IR transparent materials may be used for the IR transparent protective coating. With the IR transparent protective coating, the reflectivity of the underlying metallic alloy can be used while facilitating protection of the metallic alloy from oxidation. The IR transparent protective coating can be formed by flowing ozone while conducting a deposition operation (such as an atomic layer deposition (ALD) or chemical vapor deposition (CVD) operation) on the metallic alloy. The materials described facilitate a strong adhesion of the IR transparent protective coating to the metallic alloy.

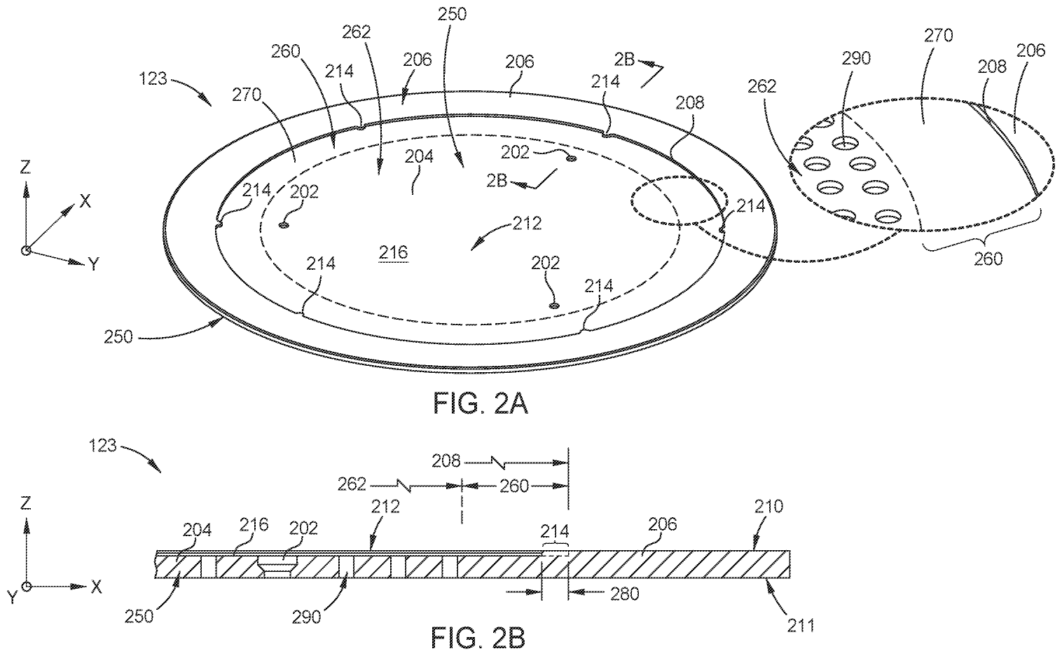

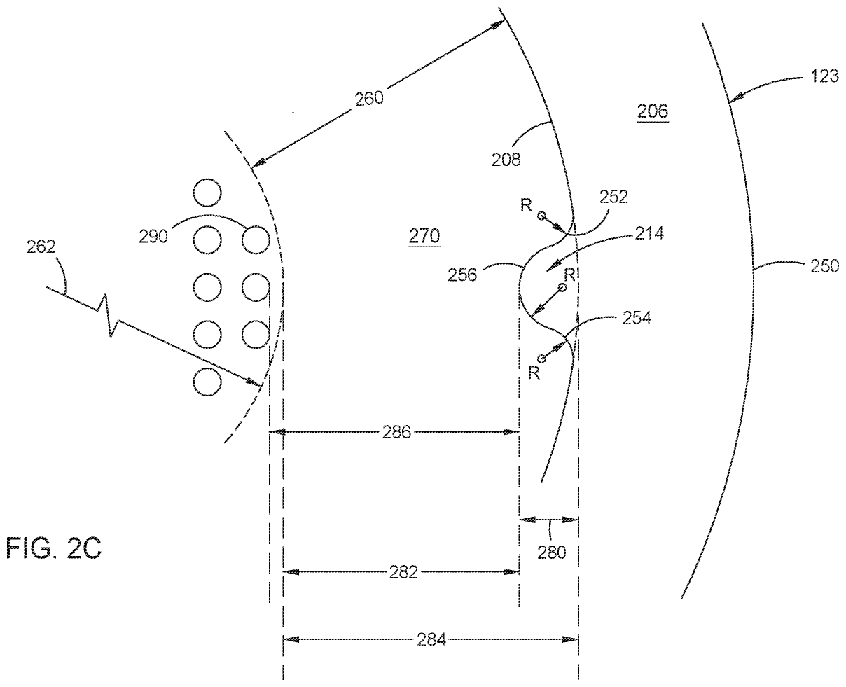

Some or all of the upper reflector 140, the lower reflector 130, the upper shell assembly 190, and the lower shell assembly 193 may be composed at least partially, such as partially or wholly, from the metallic alloy disclosed herein. The reflectivity of the metallic alloy is suitable for directing light toward the substrate 102 or away from a location where light is undesired, without the need for any additional reflective coating used in other systems, such as gold. The metallic alloy may be encased in an IR transparent protective coating as discussed above. The IR transparent protective coating may be disposed over the one or more reflective surfaces of the chamber component(s). In one or more embodiments, the IR transparent protective coating is an aluminum oxide layer. In one or more embodiments, the IR transparent protective coating has a thickness T1 (shown in FIG. 2B) within a range of about 5 nm to about 300 nm, such as within a range of about 5 nm to about 200 nm. In one or more embodiments, the thickness T1 of the IR transparent protective coating is less than 150 nm, such as less than 100 nm. In one or more embodiments, the thickness T1 is within a range of 10 nm to 100 nm, such as within a range of 10 nm to 60 nm. The IR transparent protective coating is transmissive for at least 90% (such as at least 95%, for example 98% or more) of energy (e.g., light) having a wavelength in the infrared range (such as about 700 nm to 1 mm). In one or more embodiments, the IR transparent protective coating is a magnesium fluoride layer having the thickness T1. If used, the thickness T1 of the magnesium fluoride layer may be within a range of about 20 nm to about 1 μm. The IR transparent protective coating protects the polished reflective surface(s) of the metallic alloy while having reduced or eliminated effects on the reflectivity of the metallic alloy, which may have a reflectance of 90% or more.

All, some, or none of the upper reflector 140, the lower reflector 130, the upper shell assembly 190, and the lower shell assembly 193 may be manufactured from the metallic alloy discussed herein, and/or may include one or more reflective surface(s) that are surface treated (e.g., polished) to a surface roughness (Ra) that is 15.0 nm or less. In one or more embodiments, the surface roughness (Ra) is 5.0 nm or less. In one or more embodiments, the surface roughness (Ra) is within a range of 0.2 nm to 5.0 nm. In one or more embodiments, the surface roughness (Ra) is 1.0 nm or less, such as 0.5 nm or less. Similarly, all, some or none of the upper reflector 140, the lower reflector 130, the upper shell assembly 190, and the lower shell assembly 193 may have the IR transparent protective coating coated on the one or more reflective surfaces thereof. The present disclosure contemplates that the metallic alloy, the polished reflective surface(s) thereof, and/or the IR transparent protective coating can be used for at least part of any chamber component that is used to reflect thermal energy (e.g., light).

The upper window 108 and the lower window 110 are formed of an energy transmissive material, such as quartz, and may be transparent in various embodiments, to allow heat to pass from the upper heat sources 141 and lower heat sources 143 to the substrate 102 and/or the susceptor 123 of the substrate support 106.

A processing volume 136 and a purge volume 138 are formed between the upper window 108 and the lower window 110. The processing volume 136 and the purge volume 138 are part of an internal volume defined at least partially by the upper window 108, the lower window 110, an upper liner 122, and one or more lower liners 109.

The internal (e.g., processing) volume has the substrate support 106 disposed therein. The substrate support 106 includes the susceptor 123 on which the substrate 102 is disposed. The susceptor 123 of the substrate support 106 is attached to a shaft 118 by a plurality of arms. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. In the example illustrated, the lift pin holes 107 are formed in the susceptor 123 and also the arms. The lift pin holes 107 are sized to accommodate lift pins 132 for lowering and lifting of the substrate 102 to and from the substrate support 106 before or and a deposition process is performed. The lift pins 132 may rest on lift pin stops 134 when the susceptor 123 is lowered from a process position to a transfer position. The lift pin stops 134 can be coupled to a second shaft 104 through a plurality of arms.

The flow module 112 includes a plurality of gas inlets 114, a plurality of purge gas inlets 164, and one or more gas exhaust outlets 116. In one or more embodiments, the plurality of gas inlets 114 and the plurality of purge gas inlets 164 are disposed on the opposite side of the flow module 112 from the one or more gas exhaust outlets 116. The upper liner 122 and the lower liners 109 are disposed on an inner surface of the flow module 112 and protect the flow module 112 from reactive gases used during deposition operations and/or cleaning operations. The gas inlet(s) 114 and the purge gas inlet(s) 164 are each positioned to flow a gas parallel to the top surface 150 of a substrate 102 disposed within the processing volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), hydrogen (H₂), and/or nitrogen (N₂)). One or more cleaning gases supplied using the one or more cleaning gas sources 153 can include one or more of hydrogen (H) and/or chlorine (Cl). In one or more embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. In one or more embodiments, the exhaust system 178 is disposed on an opposite side of the processing chamber 100 relative to the gas inlet(s) 114 and/or the purge gas inlets 164.

A pre-heat ring 196 is disposed outwardly of the substrate support 106. The pre-heat ring 196 is supported on a ledge of the one or more lower liners 109. In one or more embodiments, the pre-heat ring 196 and/or the liners 109, 113, and/or 122 are formed of one or more of quartz (such as transparent quartz, e.g. clear quartz; opaque quartz, e.g., white or grey quartz; and/or black quartz), silicon carbide (SiC), and/or graphite coated with SiC.

During processing, one or more process gases P1 flow from the gas inlet(s) 114, into the processing volume 136, and over the substrate 102 disposed on the susceptor 123 to form (e.g., epitaxially grow) one or more layers on the substrate 102 while the heat sources 141, 143 heat the pre-heat ring 196 and the substrate 102. After flowing over the substrate 102, the one or more process gases P1 flow out of the internal volume through the one or more gas exhaust outlets 116. The flow module 112 can be at least part of a sidewall of the processing chamber 100. The present disclosure also contemplates that one or more purge gases can be supplied to the purge volume 138 (through the plurality of purge gas inlets 164) during the deposition operation, and exhausted from the purge volume 138.

FIG. 2A is a top isometric view of one example of the susceptor 123 that may be utilized in the processing chamber 100 of FIG. 1, or other suitable processing chamber. The susceptor 123 has a substantially circular disk-shaped body 250. The disk-shaped body 250 of the susceptor 123 may be fabricated from graphite coated with silicon carbide (SiC). The body 200 may alternatively be fabricated from quartz (such as transparent quartz, e.g. clear quartz; opaque quartz, e.g., white or grey quartz; and/or black quartz), SiC, or other suitable material.

The disk-shaped body 250 has a top surface 210 and a bottom surface 211. The disk-shaped body 250 is generally symmetrical about the centerline A of the susceptor 123 (as shown in FIG. 1), and is formed from a contiguous, single mass of material, i.e., a unitary, one piece structure. The centerline A (not illustrated in FIG. 2A) of the body 250 extends perpendicular through the top and bottom surfaces 210, 211. The top surface 210 of the body 250 is generally divided into an inner region 204 and a rim 206. The rim 206 includes an inner diameter wall 208 that surrounds and bounds the inner region 204. In embodiments where the susceptor 123 is configured for use with a 300 mm substrate, the inner diameter wall 208 may have a diameter of at least 308 mm, although smaller diameters may be utilized. In certain embodiments, the inner region 204 is substantially parallel to the rim 206. A portion of the top surface 210 comprising the inner region 204 (i.e., a top surface 216 of the inner region 204) is slightly lower than the portion of the top surface 210 comprising the rim 206, thus forming substrate receiving pocket 212. The substrate receiving pocket 212 prevents the substrate 102 from slipping off of the susceptor 123 during processing. The top surface 216 of the substrate receiving pocket 212 may be coated with SiC. As shown in FIG. 2A, the top surface 216 of the substrate receiving pocket 212 is substantially flat with respect to a lateral plane of the susceptor 123 (X/Y plane). Alternatively, it is contemplated that the substrate receiving pocket 212 may be slightly concave.

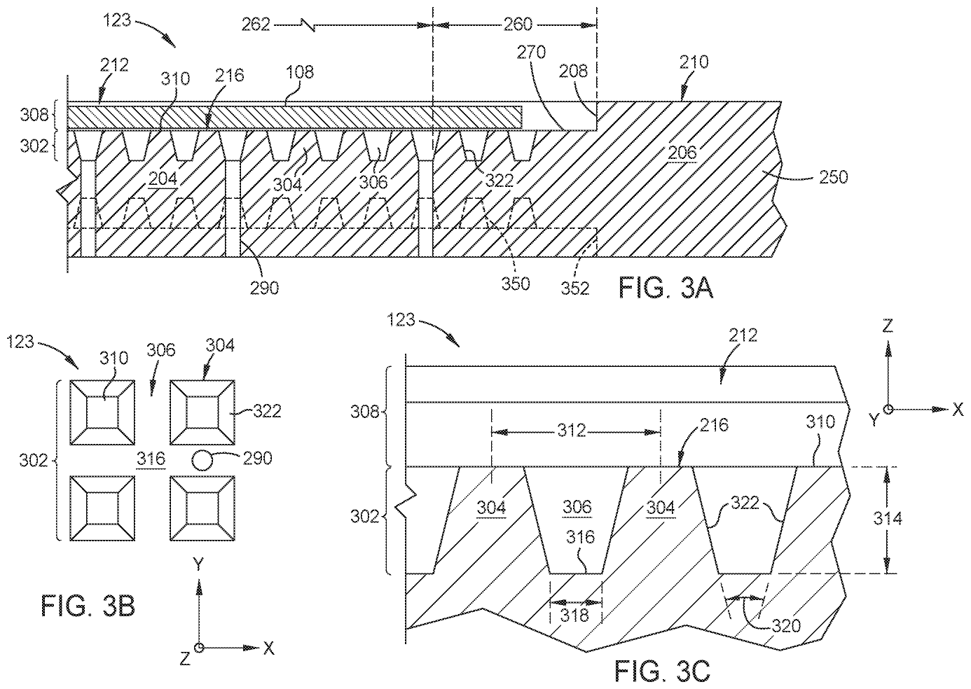

The substrate receiving pocket 212 has a depth selected to receive the substrate 102 for processing within the processing chamber 100. The inner diameter wall 208 generally forms a step (308 shown in FIG. 3A) that defines an interface between the top surface 216 of inner region 204 and the portion of the top surface 210 of the rim 206. In one embodiment, the top surface 216 of the substrate receiving pocket 212 may be about 0.5 mm to about 2.0 mm below the top surface 210 of the rim 206. Stated differently, the height of the inner diameter wall 208 may be about 0.5 mm to about 2.0 mm. The depth of the substrate receiving pocket 212 may be selected to accommodate the thickness of the substrate 102 to be supported by the susceptor 123. The substrate receiving pocket 212 has a diameter selected so that the substrate to be processed on the susceptor 123 is spaced from the inner diameter wall 208.

The top surface 216 of the substrate receiving pocket 212 is separated into two distinct regions, a non-venting region 260 and a venting region 262. The non-venting region 260 completely surrounds the venting region 262 and extends from the venting region 262 to the inner diameter wall 208 of the rim 206. The non-venting region 260 has a solid margin 270 that is devoid of holes. The venting region 262 includes two types of holes that extend through the body 250 between the top and bottom surfaces 210, 211. The first type of holes disposed in the venting region 262 are lift pin holes 202 (also labeled 107 in FIG. 1). There are generally 3 or more lift pin holes 202 formed through the body 250. The second type of holes disposed in the venting region 262 are venting holes 290. In one example, the venting holes 290 pass linearly through the body 250 to allow for more rapid and efficient venting of gas from below the substrate. The venting holes 290 generally have a diameter that is much small than a diameter of the lift pin holes 202. For example, the venting holes 290 may have a diameter that is at least a third or even half of a diameter of the lift pin holes 202. The number venting holes 290 is at least an order of magnitude greater than a number of lift pin holes 202. In some examples, the plurality of venting holes 290 formed therethrough the body 250 in the venting region 262 are arranged in an X/Y grid. In other examples, the venting holes 290 are radially aligned and/or form concentric rings. The density and/or open area of the venting holes 290 may vary across the venting region 262 such as to create regions having more venting holes 290 and/or open are compared to other regions, such as the center of the substrate receiving pocket 212 compared to the outer edge of the venting region 262 proximate the margin 270. Some venting holes 290 may have different sectional areas. Additionally, although the venting holes 290 are shown with a circular cross section, the sectional profile of the holes may be other than circular. The venting holes 290 generally allows gas to escape from between the substrate 102 and the susceptor 123 when the substrate 102 is transferred onto the susceptor 123. By allowing gas to escape, the substrate 102 is much less apt to slide on the susceptor 123 during transfer, which advantageously generates fewer particles and reduces the probability of damage to the edge of the substrate. Accordingly, the venting holes 290 contribute to greater substrate yields and longer service life of the susceptor 123.

The susceptor 123 is provided with a plurality of bumps 214, for example 3 or more bumps, extending radially inward from the inner diameter wall 208 of the rim 206 into the margin 270 of the non-venting region 260. In one example, the susceptor 123 can include 5, 6, 7, 8 or more bumps 214. The bumps 214 radially position and/or center the substrate within the substrate receiving pocket 212, while at the same time, reducing a contacting surface area between the substrate and the susceptor 123 while the substrate is supported by the susceptor 123. It may be desirable to minimize and/or reduce the contacting surface area between the substrate and the susceptor 123 in order to reduce a hot spot effect caused by higher than average heat transfer to the substrate at the outer edge. In certain embodiments, the bumps 214 may be shaped and/or aligned to reduce and/or minimize the contacting surface area thereof with an outer edge of the substrate. As shown in FIG. 2A, the bumps 214 are rounded when viewed from above. However, it is contemplated that the bumps 214 may be any suitable shape when viewed from above, such as arch-shaped, rectangular-shaped, square-shaped, V-shaped, U-shaped, C-shaped, or a combination thereof. The bumps 214 may be formed of the same material as the susceptor 123, or a different material, and may be made from silicon carbide, or graphite coated with silicon carbide or glassy carbon. It is contemplated that the substrate may contact one or more of the bumps 214 during processing without contacting the inner diameter wall 208 of the rim 206.

FIG. 2C is a partial top view of the susceptor 123 illustrating one example of a bump 214. The bump 214 generally extends a distance 280 from the inner diameter wall 208 into the margin 270 as measured using the diameter of inner diameter wall 208 as one point of origin. The distance 280 may be greater than about 3.0 mm, such as between about 3.5 mm and about 5.5 mm. The bump 214 includes a first section 256 coupled to the inner diameter wall 208 by a second section 252 and a third section 254. The second section 252 and the third section 254 connect the first section 256 to the inner diameter wall 208. The geometry of the second section 252 and the third section 254 is generally symmetrical about the midpoint of the first section 256. The second section 252 and the third section 254 have a radius that is greater than about 4.0 mm, such as about 5.0 mm to about 8.0 mm. The first section 256 has a radius that is greater than about 4.0 mm, such as about 5.0 mm to about 8.0 mm. The large radius of the first section 256 (as compared to conventional susceptors) reduces damage to the edge of the substrate 102 when disposed in the substrate receiving pocket 212 because of the increased contact area. Particularly, the combination of reduced substrate sliding due to the venting holes 290 and the large radius of the first section 256 of the bump 214 not only reduces damage to the edge of the substrate, but the gentler contact between the first section of the bump and the substrate results in the bump wearing much more slowly as compared to conventional susceptor designs, which significantly and beneficially extends the service life of the susceptor 123.

The first section 256 of the bumps 214 are generally spaced a distance 282 from the imaginary line (shown in the Figures as a dashed line) that separates the non-venting region 260 from the venting region 262. The imaginary line that separates the non-venting region 260 from the venting region 262 is generally located at a diameter S relative to the centerline A of the body 250 that is less than the diameter of the substrate 102 being supported in the substrate receiving pocket 212. In some examples, the diameter S may be less than about 298 mm, such as less than 290 mm, or even less than 285 mm. As a result, the margin 270 that is devoid of holes extends under the edge of the substrate 102, thus significantly reducing the probability of undesirable deposition gases from passing under the substrate, and more importantly, significantly reducing the probability of deposition gases undesirable passing through the venting holes 290 to the region of the processing chamber 100 below the susceptor 123. Preventing deposition gases from reaching the region of the processing chamber 100 below the susceptor 123 significantly increases the interval between chamber cleans, which beneficially increases processing throughput and production yields, while also lowering the cost of ownership.

To ensure the margin 270 extends below the edge of the substrate 102 when disposed in the substrate receiving pocket 212, the imaginary line that separates the non-venting region 260 from the venting region 262 may be disposed at least a distance 284 from the inner diameter wall 208. The imaginary line that separates the non-venting region 260 from the venting region 262 may be disposed at least a distance 282 from the bump 214. Similarly, the closes venting hole 290 may be disposed at least a distance 286 from the bump 214. In one example for a 300 mm substrate, one or more of the distances 282, 284, 286 may be selected such that the distance 282 is at least about 4 mm, such as greater than 8 mm, greater than 13 mm, or greater than 18 mm; the distance 284 is at least about 10 mm, such as greater than 15 mm, or greater than 20 mm; and/or the distance 286 is at least about 4 mm, such as greater than 8 mm, greater than 13 mm, or greater than 18 mm.

Referring back to FIG. 2B, one of the bumps 214 extending radially inward from the inner diameter wall 208 of the rim 206 toward the inner region 204. The distance 280 of each of the bumps 214 measured radially within the lateral plane of the susceptor 123 (X/Y plane) is about 2 mm to about 4 mm, such as about 3 mm. The cross-sectional view also shows one of the lift pin holes 202 and the venting holes 290 oriented orthogonally to the lateral plane (X/Y plane) of the susceptor 123 (e.g., parallel to the centerline A) and extending therethrough from the bottom surface 211 of the susceptor 123 to the top surface 216 of the substrate receiving pocket 212. Optionally, the venting holes 290 oriented non-orthogonally to the lateral plane of the susceptor 123.

FIG. 3A is an enlarged partial cross-sectional view of the exemplary susceptor 123 of FIG. 1 according to one or more embodiments, which may be combined with other embodiments disclosed herein. The susceptor 123 has a pattern 302 of substrate support posts 304 formed on the top surface 216 of the substrate receiving pocket 212. The substrate support posts 304 may be confined to the venting region 262, or alternately, extend partially or fully across the margin 270. In some examples, the substrate support posts 304 are arranged in an X/Y grid. In other examples, the substrate support posts 304 are radially aligned and/or form concentric rings. The density of substrate support posts 304 may vary across the top surface 216 such as to create regions having more support posts compared to other regions, such as the center of the vented region 262 compared to at or near the margin 270. Some substrate support posts 304 may have different sectional areas.

Although FIG. 3A only shows the profile of the pattern 302 along the X-axis, it is contemplated that the pattern substrate support posts 304 are arranged in a grid that is uniform across the top surface 216 (shown in top view of FIG. 3B). In certain embodiments, the pattern 302 has a grid layout of substrate support posts 304 in the form of truncated pyramids, separated by a plurality of channels 306. The channels 306 may have of V or other shape. The venting holes 290 are open through the body 250 to the channels 306. Each support post 304 has a substrate contact surface 310 defined at the top surface 216. The substrate contact surface 310 is recessed from the portion of the top surface 210 defining the rim 206. The substrate contact surface 310 is substantially flat and parallel with respect to a lateral plane of the susceptor 123 (X/Y plane). The substrate contact surfaces 310 are coplanar with each other for collectively contacting and supporting the substrate 102. As shown in FIG. 3B, because the support posts 304 are pyramidal, each substrate support post 304 has four sidewalls, and the V-shaped channels are oriented 90° apart.

In general, the pattern is designed to improve heat transfer uniformity from the susceptor to the substrate while, at the same time, facilitating venting of exhaust gases, for example air, from underneath the substrate. In certain embodiments, the substrate support posts 304 are evenly distributed and the substrate contact surfaces are uniformly spaced to provide uniform direct contact between the susceptor and the substrate, resulting in greater uniformity of conductive heat transfer therebetween. In certain embodiments, it may be desirable to increase the number of contact points between the susceptor and the substrate while minimizing the contacting surface area. This may be accomplished by reducing the size of each substrate contact surface as described in more detail below.

The number and/or spacing between channels may be selected to enact rapid gas exhaust from the recessed pocket. In certain embodiments, uniform spacing of the channels improves venting by lowering the total resistance to gas flow. Without channels, gases may become trapped, for example, when the substrate is initially positioned on the susceptor, during processing, or the like. If the gases remain trapped, for example, during a rapid pressure decrease in chamber pressure, the trapped gases may expand against the reduced chamber pressure causing the substrate to lift, shift, or otherwise move from its location on the susceptor.

The cross-sectional view of the pattern 302 is shown in more detail in FIG. 3C. Certain dimensions of the pattern 302 are selected to provide the advantages outlined above. For example, a lateral distance (i.e., pitch) 312 between adjacent substrate support posts 304, such as the pyramidal support posts 304 of the susceptor 123, may be about 0.5 mm to about 3 mm, such as about 1 mm to about 2 mm, such as about 1 mm, such as about 2 mm. The lateral distance 312 corresponds to the grid size of the pattern measured along the X-axis from center-to-center of adjacent substrate support posts 304 (e.g., a 1 mm grid or a 2 mm grid). The lateral distance 312 along the Y-axis may be the same or different than the lateral distance 312 along the X-axis. In the example depicted in FIGS. 3B-3C, the lateral distances 312 are the same in both the X- and Y-axes. In certain embodiments, a vertical height 314 of the substrate support posts 304 of the susceptor 123, may be about 0.25 mm to about 2 mm, such as about 0.5 mm. The vertical height 314 is measured along the z-axis from the top surface 216 to a bottom surface 316 of the channels. In certain embodiments, it may be desirable to increase the height of the substrate support post 304 to improve gas flow while, at the same time, maintaining the support feature height at a minimum to prevent cold spots from forming between the susceptor 123 and the substrate 102.

In certain embodiments, a lateral width 318 of the channels 306 of the susceptor 123 may be about 0.5 mm to about 10 mm. The lateral width 318 corresponds to the width of the bottom surface 316 of each channel measured along the X- or Y-axis between adjacent substrate support posts 304. In certain embodiments, an angle 320 of the channels 306 of the susceptor 123, measured between sidewalls 322 of adjacent substrate support posts may be about 5° to about 60° when the channels 306 have a V shape. The angle 320 may be selected to balance the reflection of radiant heat from the lamps for better temperature uniformity. In other words, because distribution of reflected and/or emitted radiation from the inner region 204 of the susceptor 123 is directional, the angle 320 can be determined such that radiant heat transfer from the susceptor 123 to the substrate 102 is increasingly isotropic (i.e., has the same value when measured in different directions). It will be appreciated that the dimensions described above also define the size of each substrate contact surface 310 along the top surface 216. It may be desirable to reduce a contacting surface area between the substrate contact surfaces 310 and the substrate 102 to allow for a higher percentage of the heat transfer to be radiant heat resulting in improved temperature control and improved thermal treatment and/or deposition on the substrate. In certain embodiments, a ratio of the total combined surface area of the substrate contact surfaces 310 to the total surface area of the substrate receiving pocket 212 inside the inner diameter wall 208 of the rim 206 measured in the X/Y plane is about 0.5% to about 5%, such as about 0.5% to about 3%, such as about 1% to about 2%. Beneficially, an ultra-low surface area ratio of the substrate contact surfaces 310, such as about 5% or less, lowers the ratio of conduction to radiation heat transfer from the susceptor 123 to the substrate 102 which improves temperature uniformity and consequently produces better processing results. Because the ratio of conduction to radiation heat transfer is positively correlated to the surface area ratio described above, further lowering of the surface area ratio can further reduce the portion of conductive heat transfer with positive impacts on processing results. Furthermore, susceptor embodiments designed with ultra-low surface area ratios beneficially provide suitable mechanical support to the substrate 102 to prevent warping while, at the same time, increasing randomly oriented radiant heat emission and reducing temperature variation between adjacent substrate support posts 304 based on precisely determined pitch between adjacent substrate support posts 304.

Optionally, the bottom surface 111 of the susceptor 123 may include a textured surface 350 and/or a recess 352. The textured surface 350 and/or the recess 352 may be a mirror image of the substrate support posts 304 and/or the substrate receiving pocket 212 such that the stresses on opposite sides (i.e., top and bottom surfaces 210, 211) the body 250 are more evenly matched, thus reducing the probability warpage of the body 250. In other examples, the textured surface 350 may be a structure substantially the inverse of the substrate support posts 304. In other examples, the recess 352 may be substantially the inverse of substrate receiving pocket 212. In still other examples, the textured surface 350 may have other dimples, ridges, slots or other surface features that break up the plane of the bottom surface 111.

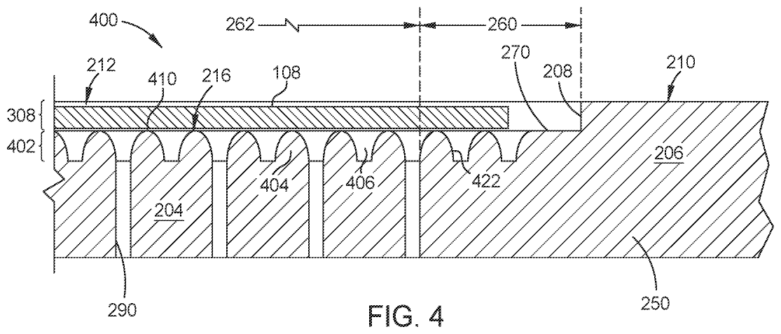

FIG. 4 is a partial cross-sectional view of a susceptor 400 that may be used in place of the susceptor 123 in the processing chamber 100 of FIG. 1 according to one or more embodiments, which may be combined with other embodiments disclosed herein. In FIG. 4, the supports 404 and channels 406 of the pattern 402 are rounded, or curved. In some other embodiments (not shown), it is contemplated that the supports 404 may be any curved shaped, such as truncated cones, truncated spherical or elliptical forms, or a combination thereof. The curved supports 404 have smooth sidewalls 422 which produce more randomly oriented thermal radiation compared to flat-faced sidewalls. Therefore, the curved supports 404 can further improve heat transfer uniformity beyond what has been discussed so far. The curved substrate contact surfaces 410 of the pattern 402 decrease the total contacting surface area between the substrate contact surfaces 410 and the substrate 102 compared to the flat substrate contact surfaces 310 of the pattern 302. The reduced contacting surface area of the susceptor 400 compared to other susceptor embodiments disclosed herein may further improve thermal uniformity when processing a substrate by lowering conductive heat transfer. In certain embodiments, a total contacting surface area between the substrate contact surfaces 410 and the substrate 102 (measured as a fraction of the surface area in the X/Y plane of the substrate receiving pocket 212 inside the inner diameter wall 208 of the rim 206) is about 0.1% to about 5%, such as about 0.1% to about 3%, such as about 0.5% to about 2%.

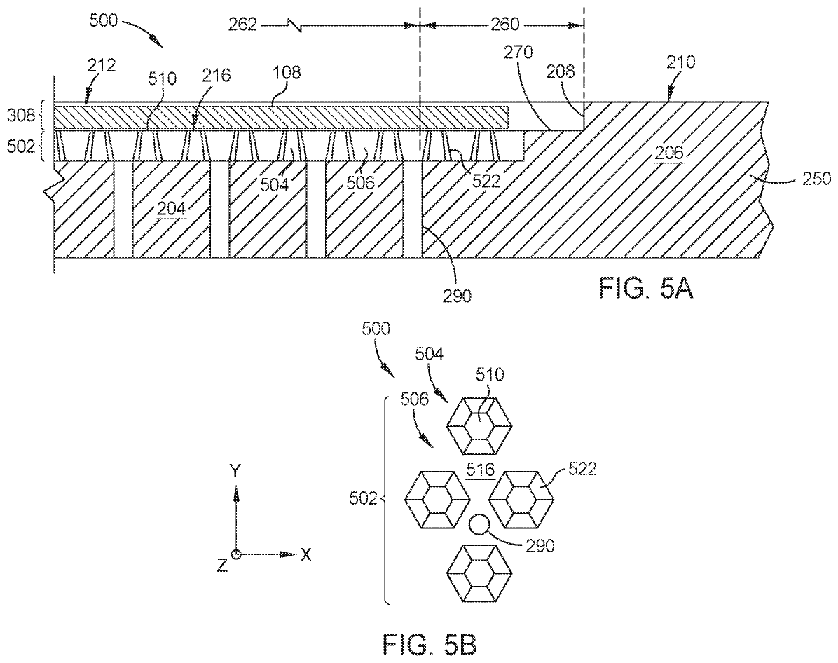

FIG. 5A is a partial cross-sectional view of a susceptor 500 that may be used in place of the susceptor 123 in the processing chamber 100 of FIG. 1 according to one or more embodiments, which may be combined with other embodiments disclosed herein. FIG. 5B is a top view of a portion of the susceptor 500. In FIGS. 5A-5B, the supports 504 and channels 506 of the pattern 502 are hexagonal when viewed from above. The substrate contact surfaces 510 of the pattern 502 are substantially flat and parallel with respect to a lateral plane of the susceptor 500 (X/Y plane) and substantially parallel to a bottom surface 516 of the channels 506, similar to the substrate contact surfaces 310 of the pattern 302. The substrate contact surfaces 510 are also coplanar with each other for collectively contacting and supporting the substrate 102. However, in contrast to the pattern 302, each support 504 of the pattern 502 has six sidewalls 522 instead of four with an associated increased in radiative surface area. The increased radiative surface area of the hexagonal supports 504 may improve heat transfer uniformity compared to pyramidal support posts 304 having the same contacting surface area. In contrast to the pattern 302, the channels 506 are oriented 60° apart instead of 90° apart. In certain embodiments, a total contacting surface area between the substrate contact surfaces 410 and the substrate 102 (measured as a fraction of the surface area in the X/Y plane of the substrate receiving pocket 212 inside the inner diameter wall 208 of the rim 206) is about 0.1% to about 5%, such as about 0.1% to about 3%, such as about 0.5% to about 2%. In some other embodiments (not shown), it is contemplated that the substrate support posts 304 may be any suitable shape when viewed from above, such as rectangular, rhombus, square, triangular, rounded, hexagonal, other shapes, or a combination thereof. In certain embodiments which may be combined with other embodiments, the substrate support posts 304 may be tetrahedral pyramids, hemispherical, other rounded shapes, other 3-dimensional shapes, or a combination thereof. Any of the substrate support posts 304 described above may be truncated to form a flat and parallel support surface across the substrate support posts 304.

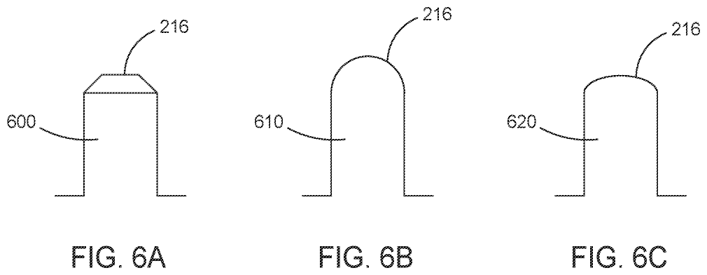

FIGS. 6A-6C illustrate some alternative examples of substrate support posts that may be utilized in place of the substrate support posts 304 described above. In FIG. 6A, a support post 600 is illustrated having a top surface 216 that is smaller in surface area than the sectional area of the post 600. In the example depicted in FIG. 6B, a support post 610 is illustrated having a top surface 216 in the form of a full round. In the example depicted in FIG. 6C, a support post 620 is illustrated having a top surface 216 that is curved, for example in the form of a dome. In still other examples, distal ends of the substrate support posts may be curved, have an edge radius or chamfer, be full round, be domed shaped or have another suitable geometry.

It should be noted that the bottom surface 111 of any of the susceptors 400, 500 described above may optionally include a textured surface 350 and/or a recess 352.

The susceptor embodiments described herein allow for more uniform temperature control of substrates during thermal processes, such as epitaxy. The temperature control is improved near the outer edge of the substrate by reducing the surface area of the outer edge contacting the susceptor, which reduces edge thermal peak and the amount of conductive heat transferred from the susceptor to the substrate at the outer edge. The embodiments disclosed herein reduce and/or minimize contacting surface area between the susceptor and the outer edge of the substrate by providing very few centering bumps, for example 3 bumps, around the circumference of the susceptor.

In general, flat pocket susceptors increase conductive heat transfer compared to susceptors which support the substrate only near the outer edge. Because conductive heat transfer between the susceptor and the substrate is more difficult to control than radiant heat transfer, reducing and/or minimizing direct contact between the susceptor and the backside of the substrate is desirable. The susceptor embodiments disclosed herein reduce direct contact between the susceptor and the backside of the substrate by providing a patterned surface having a plurality of substrate support posts, as later described below. The direct contact can be reduced based on the design of the pattern including the layout of the support posts and the dimensions of the support posts. Reducing the surface area of the substrate contacting the susceptor allows for a higher percentage of the heat transfer to be radiant heat resulting in improved temperature control and improved thermal treatment and/or deposition on the substrate. The susceptor embodiments disclosed herein also improves susceptor service life, mean time between chamber cleans, and higher production yields through the use of venting holes formed within the recessed pocket of the susceptor which significantly reduces substrate sliding within the pocket during substrate transfer. Additionally, large radius bumps for substrate centering within the pocket also contribute to improved susceptor service life, mean time between chamber cleans, and higher production yields by reducing the potential for damage to the edge of the substrate and less wear on the susceptor.

While the foregoing is directed to embodiments of the present disclosure, other and further embodiments of the disclosure may be devised without departing from the basic scope thereof, and the scope thereof is determined by the claims that follow.

What is claimed is:

1. A susceptor, comprising:
a disk shaped body having a first side and a second side, the body having a centerline extending normally through the first and second sides, the body comprising:
a rim having an inner diameter wall, the inner diameter wall defined at a first radius relative to the centerline;
an inner region circumscribed by the inner diameter wall of the rim, the inner region recessed relative to the rim to form a recessed pocket that is configured to receive a substrate;
a plurality of bumps extending radially into the inner region from the inner diameter wall of the rim;
a plurality of lift pin holes formed through the inner region; and
a venting region defined within the inner region, the venting region defined by a plurality of vent holes formed through the body, the venting region terminating at a second radius originating from the centerline, each of the plurality of vent holes having a diameter less than a diameter of each of the lift pin holes.

2. The susceptor of claim 1 further comprising:
a pattern formed in a top surface thereof, the pattern comprising a plurality of substrate support posts separated by a plurality of venting channels, the plurality of vent holes exiting the top surface into the plurality of venting channels.

3. The susceptor of claim 2, wherein each substrate support post comprises a substrate contact surface along the top surface of the inner region, and wherein a surface area ratio of the substrate contact surfaces is about 5% or less.

4. The susceptor of claim 2, wherein each substrate support post comprises a substrate contact surface along the top surface of the inner region, and wherein the substrate contact surfaces are substantially flat with respect to a lateral plane of the disk shaped body.

5. The susceptor of claim 2, wherein the substrate support posts have a curved substrate contact surface.

6. The susceptor of claim 1, wherein the second radius is at least 4.0 millimeter less than the first radius.

7. The susceptor of claim 1, wherein the second radius is at least 8.0 millimeter less than the first radius.

8. The susceptor of claim 1, wherein the second radius is at least 18.0 millimeter less than the first radius.

9. The susceptor of claim 1, wherein a first bump of the plurality of bumps further comprises:
a first section having a radius greater than about 4 mm;
a second section connecting the inner diameter wall of the rim to the first section; and
a third section connecting the inner diameter wall of the rim to the first section.

10. The susceptor of claim 9, wherein the first section of the first bump is at least 8 mm from a closest one of the plurality of vent holes.

11. The susceptor of claim 1, further comprising:
a non-venting region defined within the inner region and circumscribing the venting region, the non-venting region devoid of holes.

12. A susceptor, comprising:
a disk shaped body having a first side and a second side, the body having a centerline extending normally through the first and second sides, the body comprising:
a rim having an inner diameter wall, the inner diameter wall defined at a first radius relative to the centerline;
an inner region circumscribed by the inner diameter wall of the rim, the inner region recessed relative to the rim to form a recessed pocket that is configured to receive a substrate;
a plurality of bumps extending radially into the inner region from the inner diameter wall of the rim, the plurality of bumps configured to contact an outer edge of the substrate when the substrate is disposed in the recessed pocket, the plurality of bumps each extending into the inner region;
a plurality of lift pin holes formed through the inner region;
a venting region defined within the inner region, the venting region defined by a plurality of vent holes formed through the body, the venting region terminating at a second radius originating from the centerline, the second radius at least 4.0 millimeter less than the first radius, each of the plurality of vent holes having a diameter less than a diameter of each of the lift pin holes, the plurality of vent holes are at least 2 mm from the plurality of bumps; and
a pattern formed in a top surface of the recessed region, the pattern comprising a plurality of substrate support posts separated by a plurality of venting channels, the plurality of vent holes exiting the top surface into the plurality of venting channels.

13. The susceptor of claim 12, wherein a first bump of the plurality of bump further comprises:
a first section having a radius greater than about 4 mm;
a second section connecting the inner diameter wall of the rim to the first section; and
a third section connecting the inner diameter wall of the rim to the first section.

14. The susceptor of claim 13, wherein the first section of the first bump is at least 8 mm from the second radius.

15. The susceptor of claim 13 further comprising:
a non-venting region defined within the inner region and circumscribing the venting region, the non-venting region devoid of holes.

16. The susceptor of claim 15, wherein each substrate support post comprises a substrate contact surface along the top surface of the inner region, and wherein the substrate contact surfaces are coplanar and parallel with respect to a lateral plane of the disk shaped body.

17. The susceptor of claim 15, wherein the plurality of substrate support posts have a curved substrate contact surface.

18. The susceptor of claim 15 further comprising:
SiC coating disposed on the top surface of the recessed region.

19. A processing chamber comprising:
a chamber body having a processing volume;
a susceptor disposed in the processing volume;
a plurality of lamps positioned to radiantly heat the susceptor, the susceptor comprising:
a disk shaped body having a first side and a second side, the body having a centerline extending normally through the first and second sides, the body comprising:
a rim having an inner diameter wall, the inner diameter wall defined at a first radius relative to the centerline;
an inner region circumscribed by the inner diameter wall of the rim, the inner region recessed relative to the rim to form a recessed pocket that is configured to receive a substrate;
a plurality of bumps extending radially into the inner region from the inner diameter wall of the rim, the plurality of bumps configured to contact an outer edge of the substrate when the substrate is disposed in the recessed pocket, the plurality of bumps each extending into the inner region;
a plurality of lift pin holes formed through the inner region;
a venting region defined within the inner region, the venting region defined by a plurality of vent holes formed through the body, the venting region terminating at a second radius originating from the centerline, the second radius at least 4.0 millimeter less than the first radius, each of the plurality of vent holes having a diameter less than a diameter of each of the lift pin holes;
a non-venting region defined within the inner region and circumscribing the venting region, the non-venting region devoid of holes; and
a plurality of substrate support posts formed in the inner region.

20. The processing chamber of claim 19, wherein the substrate support posts have a curved substrate contact surface.
